(19) United States
(12) Patent Application Publication
(10) Pub. No.: US 2010/0043864 A1
(43) Pub. Date: Feb. 25, 2010

(54) Optical Support Apparatus

(75) Inventors: Peter Young, San Francisco, CA (US); Eugenia Corrales, Los Altos Hills, CA (US)

Correspondence Address: THE MUELLER LAW OFFICE, P.C., 12951 Harwick Lane, San Diego, CA, 92130, US

(73) Assignee: SOLFOCUS, INC., Mountain View, CA (US)

(21) Appl. No.: 12/197,178

(22) Filed: Aug. 22, 2008

(51) Int. Cl. H01L 31/052; H01L 31/18

(52) U.S. Cl. 136/246; 156/349; 29/592.1

(57) ABSTRACT

The present invention provides an apparatus for mounting an optical element on the underside of a substrate in a solar energy system, as a replacement for, or supplemental support to, an adhesive. The apparatus includes one or more support arms which uphold the optical element. The support arms may be secured in place by being coupled to various components of the solar energy system, such as a front panel, an enclosure, or a primary mirror.

### BACKGROUND OF THE INVENTION

Solar concentrators are solar energy generators which increase the efficiency of converting solar energy into electricity. Solar concentrators known in the art utilize, for example, various forms of mirrors and lenses for focusing incoming solar energy onto a solar cell. The resulting concentrated light enables solar concentrators to use much smaller amounts of photovoltaic material than flat panel designs, thus decreasing cost.

Components enclosed within solar concentrators can be exposed to extreme amounts of heat. For example, an optical component mounted to a glass front panel of a solar concentrator is subjected to countless hours of intense sunlight during the life of the concentrator. Over time, this extreme heat exposure can cause adhesive and material failures and consequently failure of the overall system. In particular, an optical element mounted to the bottom surface of a front panel or other substrate can cause substantial damage to other elements should its mounting joint fail. Consequently, it is highly desirable to improve the reliability of attachment methods used within a solar concentrator.

### SUMMARY OF THE INVENTION

The present invention provides an apparatus for mounting an optical element on the underside of a substrate in a solar energy system, as a replacement for, or supplemental support to, an adhesive. The apparatus includes one or more support arms which uphold the optical element. In one aspect of the invention, the support arms are configured to support the optical element with tabs, mortise and tenon joints, or by being inserted through the optical element. In another aspect of the invention, the support arms may be secured in place by being coupled to the substrate, such as a front panel. Alternatively, other components of the solar energy system, such as an enclosure or a primary mirror, may be utilized to secure the support arms.

### BRIEF DESCRIPTION OF THE DRAWINGS

Reference now will be made in detail to embodiments of the disclosed invention, one or more examples of which are illustrated in the accompanying drawings wherein:

FIG. 1 is a cross-sectional view of an optical element mounted by exemplary support arms of the present invention;

FIG. 2 is a perspective view of the optical element of FIG. 1;

FIG. 3 shows a cross-sectional view of a further embodiment of support arms for supporting an optical element;

FIGS. 4A and 4B are perspective views of exemplary arrangements of support arms with a front panel;

FIG. 5 provides a perspective view of a solar energy system with a primary mirror;

FIG. 6 is a further embodiment of support arms depicted in a cross-sectional view taken along line B-B of FIG. 5;

FIG. 7 is yet another embodiment of support arms depicted in a cross-sectional view taken along line A-A of FIG. 5; and

FIG. 8 shows a partial cross-sectional view of a solar energy array utilizing spring member support arms.

### DETAILED DESCRIPTION OF THE EMBODIMENTS

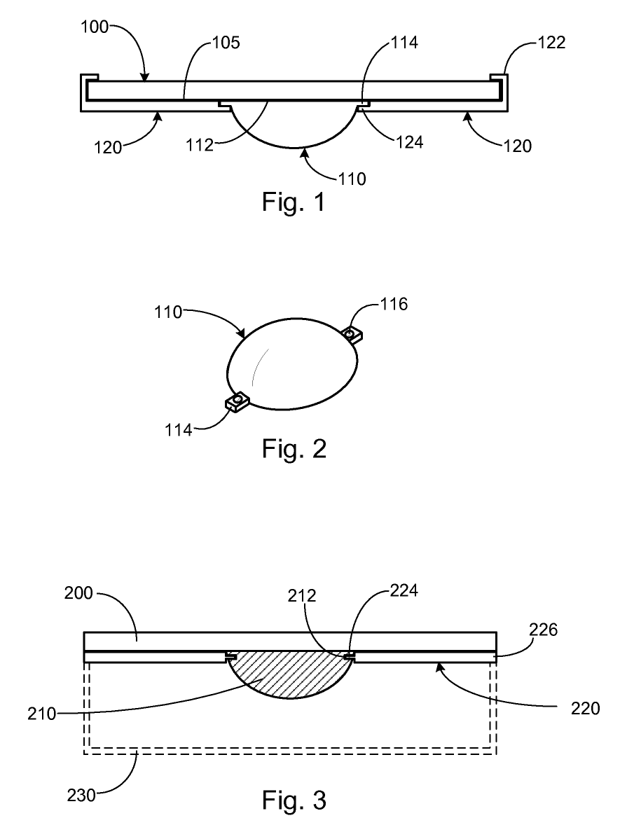

In solar energy systems such as solar concentrators, optical elements such as mirrors and lenses are utilized to redirect and focus light towards a photovoltaic cell. Some designs utilize an optical element mounted to the underside of a surface such that the optical element must resist gravity in order to stay attached to its substrate. FIG. 1 illustrates an exemplary optical element 110 mounted to a bottom surface 105 of a front panel 100. In this cross-sectional view of FIG. 1, optical element 110 may be, for example, a refracting lens or a convex mirror. It is known in the art that optical element 110 may be mounted to panel 100 with adhesive between bottom surface 105 and a base 112 of optical element 110. Adhesives can potentially fail as a result of the extreme heat exposure typical of solar energy systems, in which case a component mounted to the underside of a substrate may completely detach and render the solar energy system inoperable.

Thus in the present invention, support arms 120 are introduced to provide a beneficially redundant attachment for optical element 110, or alternatively to serve as a mechanical replacement for adhesive. Support arms 120 may be, for example, beams or rods fabricated from materials having sufficient stiffness over the desired length of support arms 120, such as aluminum or steel. Alternatively, support arms 120 may be formed from a transparent material such as polycarbonate or composite material to reduce the blockage of incoming light through panel 100. In the embodiment of FIG. 1, support arms 120 are secured to panel 100 by ends 122 which are configured with a U-shaped bend to hang from the edges of panel 100. Support arms 120 then uphold optical element 110 through the interfacing of tabs 114 of optical element 110 with tabs 124 of support arms 120. The placement of tabs 114 near base 112 preserves the majority of the surface of optical element 110 to be used for optical purposes. Tabs 114 and tabs 124 may include interlocking features such as grooves or detents to provide further stability between optical element 110 and panel 100. In addition to holding optical element 110 in place vertically against panel 100, support arms 120 may assist in the lateral positioning, such as centering, of optical element 110, on bottom surface 105 of panel 100.

In another embodiment of FIG. 1, support arms 120 may be additionally secured to panel 100 with an adhesive substance such as tape, epoxy, or putty along the length of support arms 120. Alternatively, for support arms 120 made of metal, bottom surface 105 may be metallized at the locations where support arms 120 will be attached, and then support arms 120 may be soldered in place.

FIG. 2 provides a perspective view of the optical element 110 from FIG. 1 turned upwards. In FIG. 2, tabs 114 are shown with exemplary indentations 116 which may lock with corresponding features on tabs 124 of support arms 120. Indentations 116 may also take the form of, for example, longitudinal or cross-wise grooves. Although optical element 110 is depicted with two tabs 114, it may also be configured with three or more tabs corresponding to a desired number of support arms, or may incorporate a continuous lip around the perimeter of optical element 110. Additionally, tabs 114 and mating tabs 124 may be rectangular as shown, or may have other shapes such as rounded.

FIG. 3 shows another embodiment of the present invention, in which a simplified cross-sectional view of a solar energy system includes a panel 200, an optical element 210, support arms 220, and an enclosure 230. In this embodiment, optical element 210 and support arms 220 are coupled by a mortise and tenon type of joint. Tenons 224 of support arms 220 are inserted into a matching mortise hole 212. Mortise hole 212 may be integrally formed during, for example, a glass molding process for fabricating optical element 210. FIG. 3 also shows support arms 220 with outer ends 226 being captured between panel 200 and enclosure 230, rather than being suspended from panel 100 as in FIG. 1. Brackets, flanges, or the like may be added to aid in securing support arms 220 to enclosure 230. Alternatively, cut-outs or notches may be formed in, for example, a sheet metal enclosure 230 to provide supplemental support for support arms 220.

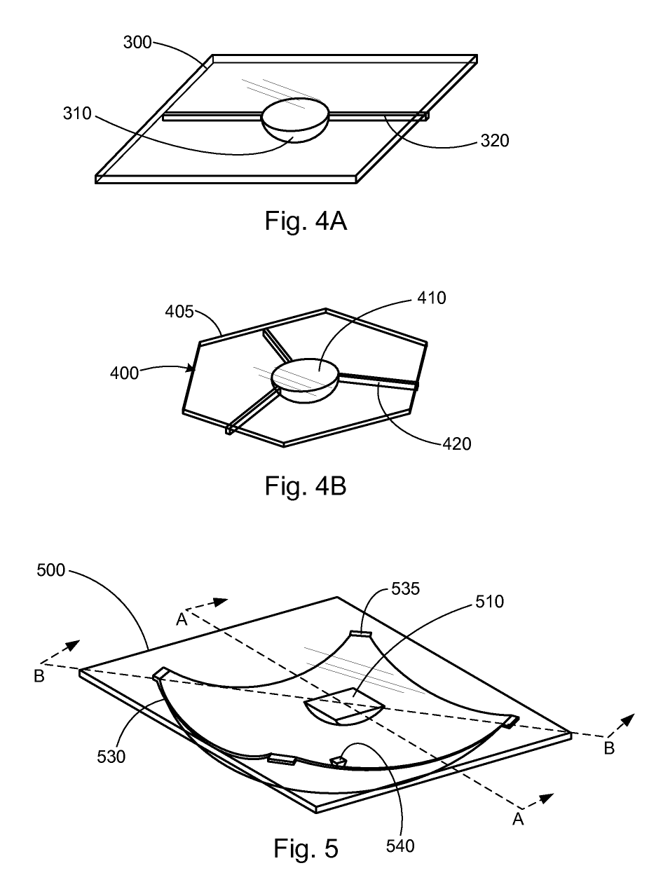

The perspective views of FIGS. 4A and 4B provide exemplary arrangements of support arms mounted in a solar energy system. FIG. 4A represents a solar energy unit having a square or rectangular front panel 300, in which an optical element 310 is mounted with two support arms 320 aligned approximately across a midline of front panel 300. In FIG. 4B, a hexagonal front panel 400 is shown with an optical element 410 and three support arms 420 radiating approximately towards the middle of edges 405 of front panel 400. Having support arms 320 and 420 aligned with the middle of the panel edges provides a shorter distance, and consequently less blockage of incoming light, than being positioned across the diagonals of the panels 300 and 400.

In the embodiments of FIGS. 4A and 4B, support arms 320 and 420 are depicted as beams with rectangular cross-sections. The rectangular sections are oriented vertically, which maximizes the strength of the support arms while minimizing obstruction of light. Other cross-sectional shapes for support arms 320 and 420 are possible, such as I-beams, circular rods, or triangular arms. Note that a larger number of support arms may be utilized than those depicted. For instance, in FIG. 4A, four support arms 320 may be orthogonally arranged to provide additional support for optical element 310 or to allow for thinner individual support arms 320 to be utilized.

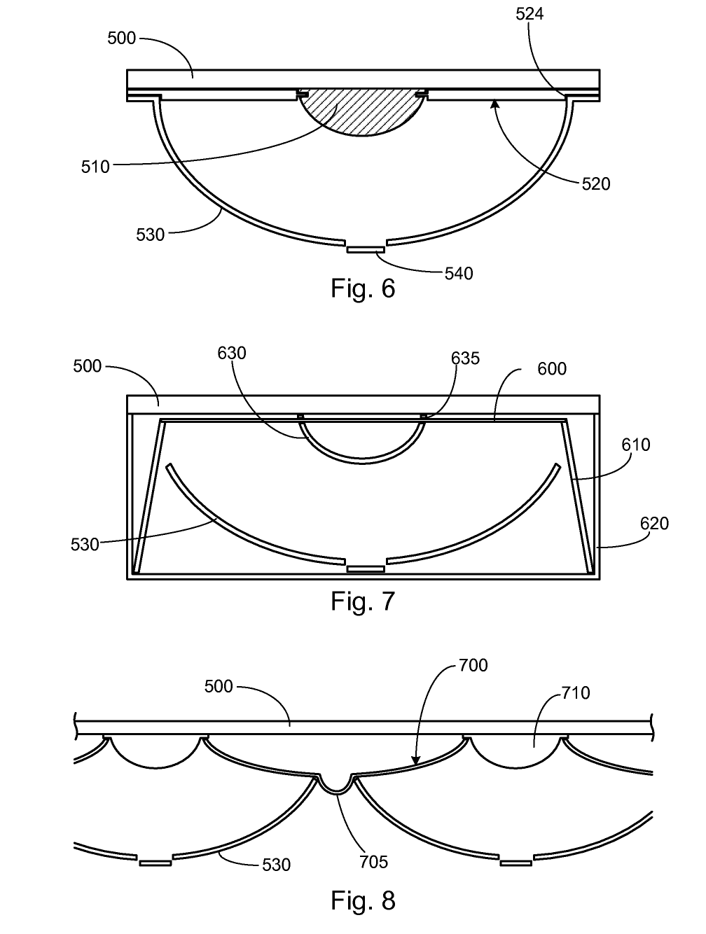

Now turning to FIG. 5, an embodiment of a solar energy system involving a panel 500, an optical element 510, and a primary mirror 530 is shown. In one configuration of this embodiment, optical element 510 is a mirror, and both optical element 510 and primary mirror 530 have substantially square perimeters. Primary mirror 530 contacts panel 500 at corners 535 of primary mirror 530. Alternatively, optical element 510 and primary mirror 530 may take other shapes such as circular or hexagonal, and may be different shapes from each other. In operation of the embodiment of FIG. 5, light enters front panel 500, reflects off of primary mirror 530 to optical element 510, which then reflects light to an optical receiver 540 for conversion to electricity. Lines A-A and B-B indicate possible orientations for support arms as shall be described in relation to FIGS. 6 and 7.

FIG. 6 illustrates an embodiment of the present invention using support arms 520 positioned along the diagonal line B-B of FIG. 5. Although the distance along the diagonal B-B of primary mirror 530 is longer than the mid-line A-A, thus obstructing more light, this positioning allows support arms 520 to be captured between the corners 535 of primary mirror 530 and panel 500. A stepped feature 524 may be incorporated into the end of support arm 520 to help in holding support arm 520 in place. In another embodiment for an array of solar energy units, support arm 520 may be doubled in length with stepped feature 524 at the center, so that a single lengthened support arm 520 may be used to support optical elements in two adjacent energy units in an array.

In the cross-sectional view of FIG. 7, yet another embodiment of the present invention is shown at the mid-line A-A of FIG. 5 where the truncated edges of primary mirror 530 do not contact panel 500. In FIG. 7, a single support arm 600 is inserted through a hollow optical element 630 having holes 635, thus upholding optical element 630. Support arm 600 is held in place by support legs 610, which may be, for example, truss-type structures or a sheet metal plate. Support legs 610 may be joined to support arm 600 by, for example, welding or mechanical fasteners, and support legs 610 may rest against an enclosure 620 for stability. In another embodiment, support arm 600 and support legs 610 may be formed together as a single part, such as by plastic injection molding, sheet metal stamping, die casting, or forming of composite materials such as graphite/epoxy.

Now turning to FIG. 8, a yet further embodiment of support arms 700 in the form of spring members is depicted in a partial array of solar energy units sectioned along the mid-line A-A of FIG. 5. Support arms 700 are fabricated from a spring material, and are leveraged on the truncated edges of primary mirror 530 to provide an upward spring force to support optical elements 710. For instance, support arms 700 may be fabricated from flat ribbon, or an increased number of support arms 700 may be fabricated from narrower wire material. In the embodiment of FIG. 8, support arms 700 are configured to bridge two adjacent solar energy units, with a curve 705 formed approximately in the center of support arm 700 to maintain the positioning of support arm 700 between units. Alternatively, support arms 700 may be configured for a single solar energy unit by using one half of the depicted configuration. Because support arms 700 are not parallel to panel 500 as in previous embodiments, the embodiment of FIG. 8 is amenable to supporting optical elements 710 against curved panels 500. In yet another embodiment of support arms 700, curve 705 may extend deeper to be supported by a back panel (e.g., the bottom of enclosure 620 of FIG. 7) of the solar energy unit, rather than leveraging off of primary mirrors 530.

While the specification has been described in detail with respect to specific embodiments of the invention, it will be appreciated that those skilled in the art, upon attaining an understanding of the foregoing, may readily conceive of alterations to, variations of, and equivalents to these embodiments. These and other modifications and variations to the present invention may be practiced by those of ordinary skill in the art, without departing from the spirit and scope of the present invention, which is more particularly set forth in the appended claims. Furthermore, those of ordinary skill in the art will appreciate that the foregoing description is by way of example only, and is not intended to limit the invention. Thus, it is intended that the present subject matter covers such modifications and variations as come within the scope of the appended claims and their equivalents.

What is claimed is:

1. A system for mounting an optical element in a solar energy unit, comprising:
a substrate having a bottom surface and a central area of the bottom surface;
an optical element having a base coupled to the central area of the substrate; and
a support arm configured to interface with the optical element near the base of the optical element, wherein the support arm supports the coupling of the optical element to the substrate.

2. The system of claim 1, wherein the optical element is coupled to the bottom surface of the substrate with an adhesive.

3. The system of claim 1, wherein the support arm comprises a plurality of support arms.

4. The system of claim 3, wherein the base of the optical element further comprises a tab, and wherein each of the support arms comprises an end forming an interfacing surface with the tab.

5. The system of claim 1, wherein a portion of the support arm is inserted into the optical element.

6. The system of claim 1, wherein the substrate has a perimeter, and wherein the support arm is coupled to the perimeter of the substrate.

7. A solar concentrator unit, comprising:
a panel having a bottom surface and a central area of the panel;
a primary mirror having a perimeter, wherein at least a portion of the perimeter is in contact with the panel;
an optical element having a base coupled to the central area of the panel; and
a support arm configured to interface with the optical element near the base of the optical element, wherein the support arm supports the coupling of the optical element to the panel.

8. The solar concentrator unit of claim 7, wherein the optical element is coupled to the bottom surface of the panel with an adhesive.

9. The solar concentrator unit of claim 7, wherein the support arm comprises a plurality of support arms.

10. The solar concentrator unit of claim 9, wherein the base of the optical element further comprises a tab, and wherein each of the support arms comprises an end forming an interfacing surface with the tab.

11. The solar concentrator unit of claim 7, wherein a portion of the support arm is inserted into the optical element.

12. The solar concentrator unit of claim 7, wherein the support arm is supported by the primary mirror.

13. The solar concentrator unit of claim 12, wherein a portion of the support arm is captured between the panel and the portion of the primary mirror that is in contact with the panel.

14. The solar concentrator unit of claim 12, wherein the support arm comprises a spring member.

15. The solar concentrator unit of claim 7, further comprising an enclosure, wherein the primary mirror is positioned between the enclosure and the panel, and wherein the support arm further comprises a support leg in contact with the enclosure.

16. A method of mounting an optical element in a solar concentrator unit, the solar concentrator unit having a panel and a primary mirror, wherein the optical element has a base, wherein the panel has a bottom surface and a central area of the bottom surface, and wherein the primary mirror has a perimeter, the method comprising:
coupling the base of the optical element to the central area of the panel;
placing a support arm in contact with the optical element, wherein the support arm is configured to interface with the optical element near the base of the optical element; and
positioning the support arm in contact with at least one of the panel and the perimeter of the primary mirror.

17. The method of mounting an optical element of claim 16, wherein the step of coupling comprises adhering the optical element to the panel.

18. The method of mounting an optical element of claim 16, wherein at least a portion of the perimeter of the primary mirror is in contact with the panel, and wherein the step of positioning the support arm comprises capturing a portion of the support arm between the panel and the portion of primary mirror which is in contact with the panel.

19. The method of mounting an optical element of claim 16, wherein the support arm comprises a plurality of support arms.
